(19) United States
(12) Patent Application Publication
(10) Pub. No.: US 2015/0221799 A1
(43) Pub. Date: Aug. 6, 2015

(54) Transformerless Photovoltaic Solar Heating System

(71) Applicant: Nate D. Hawthorn, Las Vegas, NV (US)

(72) Inventor: Nate D. Hawthorn, Las Vegas, NV (US)

(21) Appl. No.: 14/607,198

(22) Filed: Jan. 28, 2015

Related U.S. Application Data
(60) Provisional application No. 61/932,904, filed on Jan. 29, 2014.

(51) Int. Cl. H01L 31/052; H02S 40/44

(52) U.S. Cl. CPC H01L 31/0525; H02S 40/44

(57) ABSTRACT

A photovoltaic based heating system responsive to changing incident solar radiation using a electronic circuit and microprocessor with programming to track a point of maximum power of a photovoltaic cell array and to provide the maximum power collectively to at least one heating element without using a transformer.

### FIELD AND BACKGROUND OF THE INVENTION

The present invention relates to the field of solar energy. More particularly, the present invention relates to a heating system wherein the load characteristics of a resistive electric heating element are constantly matched to the power generation characteristics of a photovoltaic array having changing incident, solar radiation conditions, thereby giving maximum efficiency in heating using solar energy without using transformers or coils.

It is known that in non-electrical, solar-heating panels, the heated medium, for example, water, is heated by flowing through heating tubes absorbing radiant solar energy; free flow through the tubes is essential to the proper performance of the panels. In cold climates in which ambient air temperatures drops below the freezing point of water, there is likelihood that the water in the tubes will freeze and consequently will rupture the heating tubes or cause pumps to be damaged. In winter, cold climates cause water based heating systems to perform less efficiently. Therefore, there is a need for a durable solar heating system capable of operating efficiently in freezing and other weather conditions.

U.S. Pat. No. 5,293,447 to Fanney et al discloses an electrical solar heating system operative on photovoltaic arrays configured to adjust either the resistive load or the power generating characteristics of the photovoltaic array to maximize power transfer efficiency. Load resistance is altered by way of switching circuitry that engages a particular heating element or combination of elements to approximate the resistance associated with point of maximum power point using a sensor sensing the intensity of incident solar radiation. The shortcoming of this is that each load resistance element has a discrete resistance making it nearly impossible to achieve the target resistance associated with the second by second varying point of maximum power point. Consequently the heaters will not be operating at the maximum power at which the panels are capable of producing efficiently, thereby wasting precious solar power. Furthermore, the required plurality of heating elements adds to capital and maintenance costs.

Therefore, there is a need for a low cost, efficient, transformerless, photovoltaic array based system capable of powering standard “off-the-shelf” electrical heaters, at maximum power for any given solar irradiance conditions.

Perhaps not surprisingly, prior to this invention, most people, skilled in the art of electrical principals would think that, for example, a typical 4500 W 240V AC resistive heating element would need to be supplied by 240V at 18.75 A AC in order to create usable heat. The present invention teaches that properly modulated, pulsed DC from a photovoltaic array can be sent directly and efficiently, without a transformer, to certain “off-the-shelf” and even “un-matched” resistive heating elements creating usable heat.

Due to improvements in switching technology, such as the latest MOSFETs or high voltage IGBTs, the present invention's varying pulsed DC direct to the heating element can be achieved at high efficiency, high frequency and low power loss.

### SUMMARY OF THE INVENTION

The present invention is a photovoltaic heating system responsive to changing incident solar radiation. According to the teachings of the present invention there is provided a photovoltaic heater responsive to fluctuations in incident solar radiation intensity including: (a) a photovoltaic cell array; (b) at least one primary heating element; and (c) a maximum power point tracking circuit configured to track a point of maximum power of the photovoltaic cell array and to provide the maximum power collectively to at least one heating element.

According to a further objective of the present invention, the system also includes a medium, for example water, oil or air, wherein the at least one heating element is at least partly immersed in order to heat the medium.

According to a further objective of the present invention, the system also includes a limiting method where the pulsed DC electrical power from a photovoltaic array is never allowed to be fully DC, always having a small off period so that common “off-the-shelf” AC rated contact type thermostats can be used to control the heating temperature without arc welding the contacts together or causing undo wear or early failure.

According to a further objective of the present invention, the system also includes a detection method to detect that power is no longer being drawn by the heating element, for example when a thermostat or other switch opens or disconnects the heating element, then a circuit sends a signal to a outside device that can now use the photovoltaic array's power for other uses until needed for heating again.

According to a further objective of the present invention, the system also includes a limiting method where the operating current can be limited to within the heating control circuit's maximum operating current or be selected by the user or programmable inputs to limit the heating control circuit's operating current, thus limiting the output or input power to a certain point.

According to a further objective of the present invention, the system also includes a switch mechanism configured to reversibly connect the heating element to an electric power grid and to reversibly disconnect the heating element from the photovoltaic cell array without allowing electric grid power to enter or damage the photovoltaic heating control circuit.

According to a further objective of the present invention, the system also includes a auxiliary or secondary heating element; and a grid switch, thermostat and/or timer, the grid switch, thermostat and/or timer, configured to reversibly couple the auxiliary or secondary heating element to an electric power grid to supplement heating by at least one primary heating element.

According to a further objective of the present invention, the system also includes a conversion switch in operational connection with the grid switch, thermostat and/or timer, the conversion switch configured to enable the alternating switching of the reversibly disconnecting of the primary heating element from the photovoltaic heating control circuit when the auxiliary heating element is coupled to the electric power grid, thereby converting the photovoltaic heater into a conventional heater.

According to a further objective of the present invention, is the method also includes immersing at least a portion of the heating element in a medium to heat the medium.

There is also provided according to the teachings of the present invention, a method of photovoltaic heating including: (a) tracking a point of maximum power of a photovoltaic cell array; and (b) driving a heating element at substantially the maximum power from said photovoltaic cell array.

There is also provided according to the teachings of the present invention, a hybrid heating system including: (a) a medium to be heated; (b) a solar powered heating element at least partially submerged in a medium; (c) a photovoltaic power system operationally connected to the solar powered heating element and including: (i) a photovoltaic cell array, and (ii) a maximum power point tracking circuit configured to track a point of maximum power of the array and to provide the power to the solar powered heating element; (d) a grid powered heating element at least partially submerged in the medium; and (e) a grid switch, thermostat and/or timer, for reversibly connecting the grid powered heating element to an electric power grid.

According to a further objective of the present invention, the system also includes (f) a timer-activated thermostat configured to actuate the grid switch at a selectable time when a temperature of the medium is less than a predefined temperature, thereby automatically augmenting heating of the medium by the solar powered heating element to obtain a desired temperature.

Other objects and advantages of the present invention will become apparent from the following description of the preferred embodiments taken in conjunction with the accompanying drawings wherein like parts in each of the several figures are identified by the same reference characters.

### BRIEF DESCRIPTION OF THE DRAWINGS

The invention is herein described, by way of example only, with reference to the accompanying drawings, wherein:

FIG. 1 is a block, pictorial diagram of the photovoltaic based heating system of the present invention.

FIG. 2 is a Power-Voltage curve chart for a typical photovoltaic array.

FIG. 3 is a block, pictorial diagram of a further embodiment of the photovoltaic based heating system of the present invention.

### DESCRIPTION OF THE PREFERRED EMBODIMENTS

The present invention is a photovoltaic heating system responsive to changing incident solar radiation. Specifically, the photovoltaic heating system dynamically delivers the maximum power of a photovoltaic cell array to a resistive heating element for any given incident solar radiation. The principles and operation of the system according to the present invention may be better understood with reference to the drawings and the accompanying description.

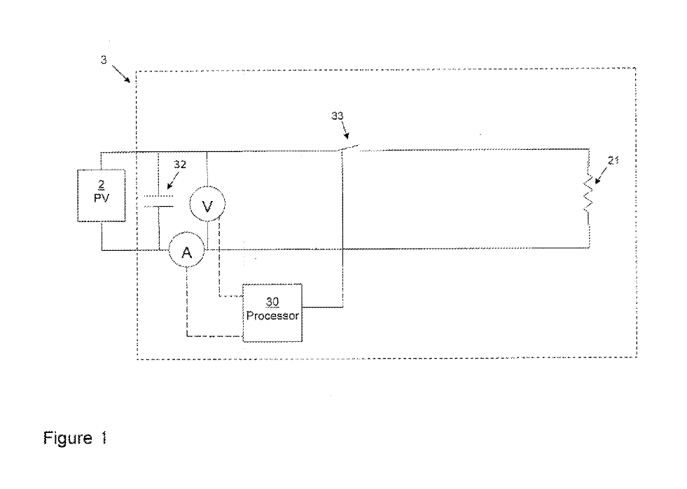

Turning now to the figures, FIG. 1 depicts a preferred embodiment of a photovoltaic heating system, including a photovoltaic (PV) cell array 2, a maximum power point tracking (MPPT) circuit 30 and 33 using a programmed microprocessor 30 to extract the maximum power possible from the PV cell array 2 at any given solar irradiance and drive a resistive heating element 21 immersed inside the medium to be heated. Typically, the medium is water contained inside a domestic hot water heater, but the medium could be a different substance, such as air or oil, depending on the intended application of the system.

The MPPT circuit includes switch 33, typically a high efficiency high amperage MOSFET or IGBT operatively linked to a microprocessor 30 configured to measure the output voltage and current of PV cell array 2. Microprocessor 30 causes the MPPT circuit to converge on an operating voltage and current associated with the maximum power output of PV cell array 2 by changing a duty cycle of switch 33 by way of Pulse-Width Modulation. The energy storing capacitor 32 stores PV cell array power for the very short period switch 33 may be off, raising the efficiency of this device and smoothing the spikes in voltage created by the switching circuit.

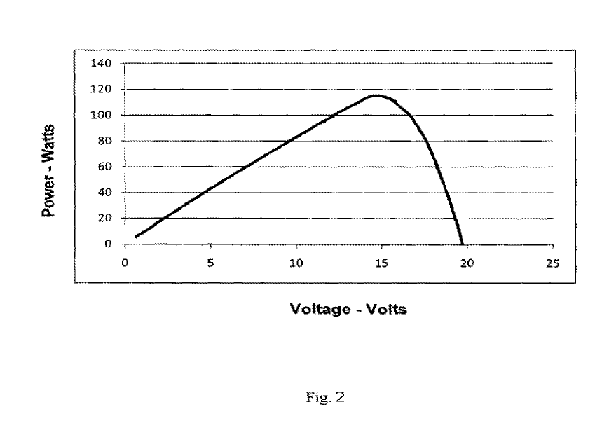

It is generally known to anyone skilled in the art of electronics relating to PV cell array power output dynamics as shown in FIG. 2, the maximum power point (MPP) drops off significantly when drawing current through a load that is drawing either a little higher current than the MPP or a little less than the MPP. This characteristic of a PV cell array 2 allows a microprocessor to easily determine the MPP of the PV cell array 2 and adjust the duty cycle of switch 33 to try to keep the operating voltage and current of the PV cell array 2 at it's MPP for any load resistance. The MPP also varies over a day with changing solar irradiance.

In this preferred embodiment method of the MPPT circuit operation, referring again to FIG. 1, first the ON time of the duty cycle of switch 33 is zero, switch 33 is open, no current is flowing and the PV cell array 2 is at it's maximum open voltage. Gradually the ON time of the duty cycle of switch 33 is increased in steps by the microprocessor 30 as it senses the operating voltage and current of the PV cell array 2, calculating the power output in watts at each step using the formula V*I=W. The microprocessor keeps increasing the ON time of the duty cycle of switch 33 in steps until it sees a drop off of the wattage from the previous step. When that point is reached it knows it has reached the upper point of the MPP and will then in steps gradually decrease the ON time of the duty cycle of switch 33 in a reverse of the previously described operation until it again sees a drop of the wattage from the previous step which is an indication it has now reached the lower point of the MPP and will then in steps gradually increase the ON time of the duty cycle of switch 33 again, repeating this over and over, thus keeping the PV cell array 2 at it's MPP range.

A small perturbation, known as “perturb and observe” is introduced intermittently during this MPPT cycle at the increasing point of the operation cycle where the microprocessor will increase the ON time of the duty cycle of switch 33 by a larger percentage, causing the PV cell array 2 to jump in voltage and current further beyond the MPP upper point than it normally would, making the system re-adjust back to the MPP point again. This intermittent perturbation is necessary to cause the MPPT system to re-track or reset back to the MPP if solar conditions have changed. The system prefers an increased ON time of the duty cycle of switch 33 so it can continue or recover from a circuit open condition such as a thermostat opening and disconnecting the heating element and then coming back on after a period of time.

It should be appreciated that any circuitry configured to determine the maximum power point and deliver a substantially maximum power is included within the scope of the present invention. MPPT circuit 30 and 33 as illustrated in FIG. 1 and described herein is only a simple example of one MPPT circuit that is suitable for the present invention. Many other types of MPPT circuits and microprocessor programs are suitable, as will be clear to those skilled in the art. Such as referenced in Esram, Trishan; P. L. Chapman (2007). “Comparison of Photovoltaic Array Maximum Power Point Tracking Techniques”. IEEE trans. on Energy Cony. 22 (2) or Bodur, Mehmet; M. Ermis (1994). “Maximum power point tracking for low power photovoltaic solar panels”. Proc. 7th Mediterranean Electrotechnical Conf.: 758-761.

In a further embodiment, referring again to FIG. 1 and the above description, the ON time of the duty cycle of switch 33 is also limited and not allowed to go to 100% ON, meaning a small OFF or ZERO pulse or period is always present so that common “off-the-shelf” AC rated contact type thermostats can be used to switch the heating element on and off at a particular temperature without arc welding the contacts together or causing undo wear or early failure.

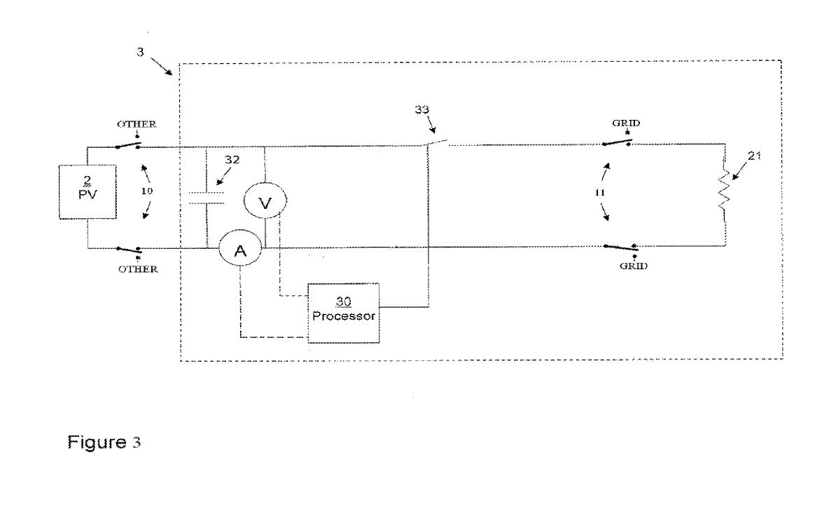

In a further embodiment, referring again to FIG. 1 and the above description, the microprocessor 30 also senses and monitors the operating voltage and current to detect that power is no longer being drawn by the heating element, for example when a thermostat or other switch opens or disconnects the heating element, watching for a large current drop and/or voltage rise, or seeing that the voltage doesn't drop when the ON time of the duty cycle of switch 33 is at its maximum and the PV cell array 2 should be fully loaded, or that the current does not rise at all, or all or a combination of these methods, then microprocessor 30 sends a signal to a outside device that can now use the PV cell array's 2 power for other uses until needed for heating again. This could be done through FIG. 3 relay or switch 10 or other parallel connected outside device to the PV cell array's 2 power.

In a further embodiment, referring again to FIG. 1 and the above description, the microprocessor 30 also senses and monitors the operating current and limits it by decreasing the ON time of the duty cycle of switch 33 whenever the current increases above a set point, thus limiting the output or input power to a certain point.

In a further embodiment, referring again to FIG. 1 and FIG. 3 and the above description, the microprocessor 30 also senses and monitors the operating voltage and current to detect that power is no longer being produced by the PV cell array 2 and can then send a signal to a relay or switch 11 which can reversibly connect the heating element to an electric power grid and to reversibly disconnect the heating element from the photovoltaic cell array without allowing electric grid power to enter or damage the photovoltaic heating control circuit.

In a further embodiment, referring again to FIG. 1 and the above description, a auxiliary or secondary heating element is also immersed inside the medium to be heated and a grid switch, thermostat and/or timer, the grid switch, thermostat and/or timer, configured to reversibly couple the auxiliary or secondary heating element to an electric power grid to supplement heating by the primary heating element creating a hybrid heating system. It should be further appreciated that heating a medium having any number of heating elements is also included in the scope of the present invention.

In a further embodiment, referring again to FIG. 1 and the above description, a conversion switch in operational connection with a grid switch, thermostat and/or timer, the conversion switch configured to enable the alternating switching of the reversibly disconnecting of the primary heating element from the photovoltaic heating control circuit when the auxiliary or secondary heating element is coupled to the electric power grid, thereby converting the said heater into a conventional heater.

It is generally known to anyone skilled in the art of electronics that as the resistance of a heating element increases, the voltage sent to said heating element must increase to get any usable heat out of the element. Thus the voltage of the PV cell array must be increased to accommodate higher resistance heating elements and to allow the described MPPT circuit to operate properly. If the proper voltage range of a particular PV cell array is selected then standard “off-the-shelf” resistive heating elements can be used also allowing existing equipment to be operated without changing the heating element. However, with the design of the described present invention, the voltage can increase from adding more PV cells in series circuit well above the normal operating voltage of said heating element, keeping the current the same, and the MPPT circuit will still find and track the maximum power point of the PV cell array, sending the maximum power to said heating element.

It should be noted that any embodiment employing PV or grid power, either simultaneously or alternatively is considered to be a hybrid heater for the sake of this document.

It should be appreciated that any combination of any of the above-described features is included within the scope of the present invention.

It should be appreciated that that the present invention is capable of powering any resistance heating device.

It should be noted that the present invention is highly efficient, light weight, simple to install and to manage, and inexpensive.

It will be appreciated that the above descriptions are intended only to serve as examples, and that many other embodiments are possible within the scope of the present invention as defined in the appended claims.

What is claimed is:

1. Apparatus for heating a medium that is responsive to fluctuations in incident solar radiation intensity, using the energy of incident solar radiation, comprising: (a) an array of photovoltaic cells for generating electrical energy responsive to incident solar radiation, the efficiency of said generation varying dependent on the intensity of the incident radiation; (b) at least one primary resistive heating element; and (c) a maximum power point tracking and switching circuit configured to use sensed voltage and current to track a point of maximum power of said photovoltaic cell array and to provide said maximum power collectively to said at least one primary resistive heating element, wherein said switching circuit uses no transformer.

2. The apparatus of claim 1, further comprising: (d) a medium wherein said at least one primary resistive heating element is at least partly immersed in order to heat said medium.

3. The apparatus of claim 2, wherein said medium is selected from the group consisting of oil, water, or air.

4. The apparatus of claim 1, further comprising: (d) a limiting circuit where the pulsed DC electrical power from the said maximum power point tracking and switching circuit is never allowed to be fully 100% DC, thus always having a small off period in order to prevent in circuit switches or thermostats from arc welding the contacts together or causing undo wear or early failure.

5. The apparatus of claim 1, further comprising: (d) a detection circuit to detect that power is no longer being drawn by the said resistive heating element, sending a signal to a outside device indicating that the said photovoltaic cell array can be used for other purposes.

6. The apparatus of claim 1, further comprising: (d) a limiting circuit where the operating current can be limited to within the heating control circuit's maximum operating current or be selected by the user or programmable inputs to limit the heating control circuit's operating current, in order to limit the output or input power to a certain point.

7. The apparatus of claim 1, further comprising: (d) a switch mechanism configured to reversibly connect said resistive heating element to an electric power grid and to reversibly disconnect said resistive heating element from said maximum power point tracking and switching circuit.

8. The apparatus of claim 1, further comprising: (d) an auxiliary or secondary heating element; and (e) a grid switch, thermostat and/or timer, said grid switch, thermostat and/or timer, configured to reversibly couple said auxiliary or secondary heating element to an electric power grid to supplement heating by said at least one primary resistive heating element.

9. The apparatus of claim 8, further comprising: (f) a conversion switch in operational connection with said grid switch, thermostat and/or timer, said conversion switch is configured to enable the alternating switching of the reversibly disconnecting of the primary heating element from the photovoltaic heating control circuit when the auxiliary heating element is coupled to the electric power grid, thereby converting the photovoltaic heater into a conventional heater in that only one heating element is on at a time.

10. The apparatus of claim 1, further comprising: (d) a energy storage capacitor connected parallel to said array of photovoltaic cells.

11. A method for heating a medium using the energy of solar radiation, comprising the steps of: (a) exposing a photovoltaic cell array to incident solar radiation, said array comprising a number of separately connectable cells, each cell generating power responsive to incident solar radiation; (b) tracking a point of maximum power of said photovoltaic cell array using a circuit that senses voltage and current; (c) connecting said photovoltaic cell array through a switching circuit to a resistive heating element; and (d) switching said switching circuit on and off at varying pulse widths according to said maximum power tracking information thus driving the said resistive heating element at substantially said maximum power.

12. The method of claim 11, further comprising the step of: (e) immersing at least a portion of said resistive heating element in a medium to heat said medium.

13. The method of claim 12, wherein said medium is selected from the group consisting of oil, water, or air.

14. The method of claim 11, further comprising the step of: (e) limiting the pulsed DC electrical power from the said maximum power point tracking and switching circuit is never allowed to be fully DC, thus always having a small off period, never being fully on.

15. The method of claim 11, further comprising the step of: (e) detecting that power is no longer being drawn by the said resistive heating element and sending a signal to a outside device indicating that the said photovoltaic cell array can be used for other purposes.

16. The method of claim 11, further comprising the step of: (e) limiting the operating current to within the heating control circuit's maximum operating current or be selected by the user or programmable inputs to limit the heating control circuit's operating current, in order to limit the output or input power to a certain point.

17. A hybrid heating system comprising: (a) a medium to be heated; (b) a solar powered heating element at least partially submerged in said medium; (c) a photovoltaic power system operationally connected to said solar powered heating element and including: (i) a photovoltaic cell array, and (ii) a maximum power point tracking circuit configured to track a point of maximum power of said array and to provide said power to said solar powered heating element without a transformer; (d) a grid powered heating element at least partially submerged in said medium; and (e) a grid switch for reversibly connecting said grid powered heating element to an electric power grid.

18. The hybrid heating system of claim 17, further comprising (f) a timer-activated switch configured to actuate said grid switch at a selectable time, thereby automatically augmenting heating of said medium by said solar powered heating element to a certain time.

19. The hybrid heating system of claim 17, further comprising (f) a thermostat configured to actuate said grid switch when a temperature of said medium is less than a predefined temperature, thereby automatically augmenting heating of said medium by said solar powered heating element to obtain a desired temperature.
